(19) United States
(12) Patent Application Publication
(10) Pub. No.: US 2026/0318745 A1
(43) Pub. Date: Oct. 15, 2026

(54) PYROELECTRIC DETECTOR HAVING SUPPORT STRUCTURE WITH MEMBRANE

(71) Applicant: Skyworks Solutions, Inc., Irvine, CA (US)

(72) Inventor: Nasser Mohamed Razek, Bern (CH)

(21) Appl. No.: 19/548,421

(22) Filed: Feb. 24, 2026

Related U.S. Application Data
(60) Provisional application No. 63/767,787, filed on Mar. 6, 2025.
(60) Provisional application No. 63/767,782, filed on Mar. 6, 2025.
(60) Provisional application No. 63/767,774, filed on Mar. 6, 2025.

(51) Int. Cl. G01J 5/22

(52) U.S. Cl. CPC G01J 5/22

(57) ABSTRACT

A pyroelectric detector is disclosed. The pyroelectric detector can include a pyroelectric element that includes a first electrode, a second electrode, a pyroelectric layer between the first electrode and the second electrode, an absorber, and a first bonding layer. The pyroelectric detector can include a support structure that includes a substrate having a cavity, a membrane, and a second bonding layer bonded to the first bonding layer to define a bonding interface layer. The cavity and the membrane are positioned laterally between portions of the substrate.

### INCORPORATION BY REFERENCE TO ANY PRIORITY APPLICATIONS

This application is a non-provisional application that claims the benefit of U.S Provisional Patent Application No. 63/767,787, filed Mar. 6, 2025, U.S. Provisional Patent Application No. 63/767,782, filed Mar. 6, 2025, and U.S. Provisional Patent Application No. 63/767,774, filed Mar. 6, 2025, the entireties of which are hereby incorporated by reference herein and made a part of the present disclosure. Any and all applications for which a foreign or domestic priority claim is identified in connection with the present application are hereby incorporated by reference under 37 C.F.R. § 1.57 in their entirety herein and made a part of the present disclosure.

### BACKGROUND

### Technical Field

Embodiments of this disclosure relate to pyroelectric detectors and methods of manufacturing a pyroelectric detector.

### Description of Related Technology

Pyroelectric infrared detectors detect infrared radiation by using materials that generate an electric signal in response to temperature changes. The pyroelectric infrared detectors can be designed to operate without the need for cooling systems, making them efficient and practical for various applications. These detectors are widely used in areas such as motion sensing, thermal imaging, and industrial monitoring.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a pyroelectric detector including: a pyroelectric element; and a support structure covalently bonded to the pyroelectric element, the support structure including a substrate.

In some embodiments, the techniques described herein relate to a pyroelectric detector wherein the pyroelectric element includes a first electrode, a second electrode, a pyroelectric layer between the first electrode and the second electrode, and an absorber.

In some embodiments, the techniques described herein relate to a pyroelectric detector wherein the pyroelectric layer includes a piezoelectric layer.

In some embodiments, the techniques described herein relate to a pyroelectric detector wherein the pyroelectric element further includes a first oxide layer on a surface of the first electrode and the support structure further includes a second oxide layer covalently bonded to the first oxide layer defining a bonding interface layer.

In some embodiments, the techniques described herein relate to a pyroelectric detector wherein the absorber is positioned laterally between portions of the second electrode.

In some embodiments, the techniques described herein relate to a pyroelectric detector wherein the second electrode is positioned between the pyroelectric layer and the absorber.

In some embodiments, the techniques described herein relate to a pyroelectric detector wherein the bonding interface layer has a thickness less than 2 micrometers.

In some embodiments, the techniques described herein relate to a pyroelectric detector wherein the thickness of the bonding interface layer is in a range between 0.6 micrometers and 1.4 micrometers.

In some embodiments, the techniques described herein relate to a pyroelectric detector wherein the substrate has a first portion, a second portion, and a cavity laterally between the first portion and the second portion.

In some embodiments, the techniques described herein relate to a pyroelectric detector wherein the cavity is positioned below the absorber.

In some embodiments, the techniques described herein relate to a pyroelectric detector wherein the support structure further includes a membrane between the cavity and the first electrode, and a thickness of the membrane is in a range between 20 micrometers and 30 micrometers.

In some embodiments, the techniques described herein relate to a pyroelectric detector wherein the membrane is positioned between the first portion and the second portion of the substrate.

In some embodiments, the techniques described herein relate to a pyroelectric detector wherein the membrane is in contact with the bonding interface layer.

In some embodiments, the techniques described herein relate to a pyroelectric detector wherein the substrate includes silicon or sapphire.

In some aspects, the techniques described herein relate to a pyroelectric detector including: a pyroelectric element including a first electrode, a second electrode, a pyroelectric layer between the first electrode and the second electrode, an absorber, and a first oxide layer; a support structure including a substrate, a membrane, and a second oxide layer covalently bonded to the first oxide layer; and a bonding interface layer including the first oxide layer and the second oxide layer, the bonding interface layer positioned between the first electrode of the pyroelectric element and the support structure.

In some embodiments, the techniques described herein relate to a pyroelectric detector wherein the bonding interface layer has a thickness less than 2 micrometers.

In some embodiments, the techniques described herein relate to a pyroelectric detector wherein the thickness of the bonding interface layer is in a range between 0.6 micrometers and 1.4 micrometers.

In some embodiments, the techniques described herein relate to a pyroelectric detector wherein the substrate has a first portion, a second portion, and a cavity laterally between the first portion and the second portion.

In some embodiments, the techniques described herein relate to a pyroelectric detector wherein the membrane is positioned between the first portion and the second portion of the substrate, and a thickness of the membrane is in a range between 20 micrometers and 30 micrometers.

In some embodiments, the techniques described herein relate to a pyroelectric detector wherein the membrane is in contact with the bonding interface layer.

In some aspects, the techniques described herein relate to a method of forming a pyroelectric detector, the method including: providing a pyroelectric structure including a pyroelectric layer and a first electrode and a substrate structure including a substrate; forming a first bonding layer on the first electrode; forming a second bonding layer on the substrate; and fusion bonding the first bonding layer and the second bonding layer to form a bonding interface layer.

In some embodiments, the techniques described herein relate to a method wherein the first bonding layer and the second bonding layer are oxide layers.

In some embodiments, the techniques described herein relate to a method wherein forming the first bonding layer includes preparing the first bonding layer for bonding.

In some embodiments, the techniques described herein relate to a method wherein preparing the first bonding layer includes polishing a surface of the first bonding layer by way of chemical-mechanical polishing.

In some embodiments, the techniques described herein relate to a method wherein preparing the first bonding layer further includes treating the surface of the first bonding layer by way of plasma activation and ultraviolet irradiation.

In some embodiments, the techniques described herein relate to a method wherein forming the second bonding layer includes preparing the second bonding layer for bonding.

In some embodiments, the techniques described herein relate to a method wherein preparing the second bonding layer includes polishing a surface of the second bonding layer by way of chemical-mechanical polishing.

In some embodiments, the techniques described herein relate to a method wherein preparing the second bonding layer further includes treating the surface of the second bonding layer by way of plasma activation and ultraviolet irradiation.

In some embodiments, the techniques described herein relate to a method further including thinning the pyroelectric layer.

In some embodiments, the techniques described herein relate to a method wherein thinning the pyroelectric layer includes thinning the pyroelectric layer to a thickness in a range between 0.5 micrometers and 50 micrometers.

In some embodiments, the techniques described herein relate to a method further including polishing a surface of the pyroelectric layer and forming a second electrode over the surface of the pyroelectric layer.

In some embodiments, the techniques described herein relate to a method further including providing an absorber such that the pyroelectric layer is positioned between the absorber and the first electrode.

In some embodiments, the techniques described herein relate to a method further including forming a cavity in the substrate.

In some embodiments, the techniques described herein relate to a method wherein the cavity extends completely through a thickness of the substrate and exposes the bonding interface layer.

In some embodiments, the techniques described herein relate to a method further including forming a membrane on the exposed surface of the second bonding layer.

In some embodiments, the techniques described herein relate to a method further including partially filling the cavity with silicon dioxide or silicon nitride.

In some embodiments, the techniques described herein relate to a method wherein fusion bonding the first bonding layer and the second bonding layer includes annealing at a temperature below 250°C.

In some aspects, the techniques described herein relate to a method of forming a pyroelectric infrared detector, the method including: forming a first oxide bonding layer on a surface of a pyroelectric structure including a first electrode and a pyroelectric layer; forming a second oxide bonding layer on a surface of a support structure; and directly bonding the first oxide bonding layer and the second oxide bonding layer.

In some embodiments, the techniques described herein relate to a method further including: forming a pyroelectric element by forming a second electrode and providing an absorber; forming a cavity in the support structure; and forming a membrane by partially filling the cavity with a membrane material.

In some aspects, the techniques described herein relate to a method of forming a pyroelectric infrared detector, the method including: preparing a surface of a pyroelectric structure for bonding by way of plasma activation and ultraviolet irradiation; preparing a surface of a support structure for bonding by way of plasma activation and ultraviolet irradiation; and bonding the surface of the pyroelectric structure and the surface of the support structure.

In some aspects, the techniques described herein relate to a pyroelectric detector including: a pyroelectric element including a first electrode, a second electrode, a pyroelectric layer between the first electrode and the second electrode, an absorber, and a first bonding layer; and a support structure including a substrate having a cavity, a membrane, and a second bonding layer bonded to the first bonding layer to define a bonding interface layer, the cavity and the membrane being positioned laterally between portions of the substrate.

In some embodiments, the techniques described herein relate to a pyroelectric detector wherein the first bonding layer and the second bonding layer are oxide layers.

In some embodiments, the techniques described herein relate to a pyroelectric detector wherein the membrane includes silicon nitride.

In some embodiments, the techniques described herein relate to a pyroelectric detector wherein the first bonding layer has a thickness in a range between 0.3 micrometers and 0.7 micrometers.

In some embodiments, the techniques described herein relate to a pyroelectric detector wherein the second bonding layer has a thickness in a range between 0.3 micrometers and 0.7 micrometers.

In some embodiments, the techniques described herein relate to a pyroelectric detector wherein the membrane has a thickness in a range between 20 micrometers and 30 micrometers.

In some embodiments, the techniques described herein relate to a pyroelectric detector wherein the membrane is in contact with the bonding interface layer.

In some embodiments, the techniques described herein relate to a pyroelectric detector wherein the membrane is in contact with the first electrode.

In some embodiments, the techniques described herein relate to a pyroelectric detector wherein the substrate includes silicon or sapphire.

In some embodiments, the techniques described herein relate to a pyroelectric detector wherein the cavity has a tapered sidewall.

In some embodiments, the techniques described herein relate to a pyroelectric detector wherein the pyroelectric layer includes lithium tantalate or lithium niobate.

In some embodiments, the techniques described herein relate to a pyroelectric detector wherein the absorber is an infrared absorber.

In some aspects, the techniques described herein relate to a pyroelectric detector including: a substrate having a first portion, a second portion, and a cavity laterally between the first portion and the second portion; a pyroelectric layer between a first electrode and a second electrode, the pyroelectric layer coupled to the substrate; and a membrane positioned laterally between the first portion and the second portion of the substrate, a thickness of the membrane being in a range between 20 micrometers and 30 micrometers.

In some embodiments, the techniques described herein relate to a pyroelectric detector wherein the membrane includes silicon nitride.

In some embodiments, the techniques described herein relate to a pyroelectric detector wherein the membrane has a thickness in a range between 15 micrometers and 30 micrometers.

In some embodiments, the techniques described herein relate to a pyroelectric detector further including a bonding interface layer between the substrate and the first electrode, wherein the membrane is in contact with the bonding interface layer.

In some embodiments, the techniques described herein relate to a pyroelectric detector wherein the membrane is in contact with the first electrode.

In some embodiments, the techniques described herein relate to a pyroelectric detector wherein the substrate includes silicon or sapphire.

In some embodiments, the techniques described herein relate to a pyroelectric detector wherein the cavity has a tapered sidewall.

In some embodiments, the techniques described herein relate to a pyroelectric detector wherein the pyroelectric layer includes lithium tantalate or lithium niobate.

The present disclosure relates to U.S. Patent Application No. _________ [Attorney Docket SKYWV-1579A1], titled “PYROELECTRIC DETECTOR WITH PYROELECTRIC ELEMENT,” and U.S. Patent Application No. _________ [Attorney Docket SKYWV-1579A2], titled “METHODS OF MANUFACTURING PYROELECTRIC DETECTORS,” filed on even date herewith, each of which is hereby incorporated herein by reference in its entirety.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a pyroelectric infrared detector according to an embodiment.

FIGS. 2A-2E, 3A, 3B, and 4A-4F illustrate a method of manufacturing the pyroelectric infrared detector according to one or more embodiments.

FIG. 5 is a flowchart of a method of forming a pyroelectric detector according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Pyroelectric infrared detectors can detect infrared radiation by harnessing the pyroelectric effect of pyroelectric ceramics or polar dielectric materials like lithium tantalate (LiTaO₃ or LT) and lithium niobate (LiNbO₃ or LN), which are types of piezoelectric materials. These materials are particularly suitable for pyroelectric sensors due to their high pyroelectric coefficient, low dielectric constant, low dielectric loss, and low heat capacitance. The pyroelectric effect occurs in polar materials and generates surface charges proportional to the temperature change. The sensor’s basic structure can include a planar capacitor. The charge Q can be calculated by the equation Q=ApΔT, where A is the capacitor area, p is the pyroelectric coefficient, and ΔT is the temperature variation. This structure enables the sensor to directly generate an electric signal in response to infrared radiation, allowing seamless integration into electronic systems.

Uncooled pyroelectric infrared detectors are designed to operate at ambient temperatures without cooling mechanisms such as cryogenic or thermoelectric systems. This design can make the uncooled pyroelectric infrared detectors energy-efficient, cost-effective, and highly practical for a wide range of applications. Uncooled pyroelectric infrared detectors are widely used in motion detection for security systems and automatic lighting, as well as in gas analysis, temperature monitoring, and industrial process control. Also, uncooled pyroelectric infrared detectors can be integral to thermal imaging devices, which can be used in, for example, medical diagnostics.

A pyroelectric infrared detector can include a pyroelectric element bonded to a substrate by way of bump bonding. The pyroelectric element includes a first electrode, a second electrode, a polar dielectric material between the first and second electrodes, and an absorber. The polar dielectric material can generate an electric charge in response to temperature changes caused by absorbed infrared (IR) radiation. The first and second electrodes can be connected in series with opposite polarities, which helps cancel out noise from environmental fluctuations while amplifying the desired signal.

The substrate, to which the pyroelectric element is attached, can provide mechanical support to the relatively thin and delicate pyroelectric element, ensuring durability and stability in various applications. The substrate can function as a thermal isolator, reducing interference from environmental temperature changes and ensuring that the pyroelectric element responds predominantly to IR radiation. Substrate materials such as silicon, glass, or ceramics can be selected for their thermal and electrical properties.

Pyroelectric infrared detectors with substrate-mounted elements can be employed in motion detection systems, such as those used in security alarms and automatic lighting, as well as in gas analysis for identifying specific gases through their IR absorption spectra. Pyroelectric infrared detectors can also be beneficial in thermal imaging for medical diagnostics, building inspections, and industrial monitoring.

Using bonding techniques, such as bump bonding, for bonding the pyroelectric element to the substrate can involve complex and costly methods that may lead to limitations in sensitivity, response time, and material integration. Therefore, there is a continuing need for a method that allows creation of a high-performance infrared detector with improved sensitivity and reduced manufacturing costs, low thermal mass, and good thermal imaging.

Embodiments disclosed herein relate to uncooled pyroelectric infrared detectors that can operate at room temperature without a cooling system. The uncooled pyroelectric infrared detectors in accordance with principles and advantages disclosed herein can provide improved sensitivity and reduced manufacturing costs. An uncooled pyroelectric infrared detector includes a pyroelectric element and a support structure bonded (e.g., covalently bonded) to the pyroelectric element. The pyroelectric element can include a first electrode, a second electrode, a pyroelectric layer between the first electrode and the second electrode, an absorber, and a first oxide layer on a surface of the first electrode. The support structure can include a substrate and a second oxide layer bonded to the first oxide layer. The substrate can have a first portion, a second portion, and a cavity laterally between the first portion and the second portion. Pyroelectric detectors can detect radiation in a range between, for example, 1 micrometer to 100 micrometers while operating at room temperature. Although a pyroelectric infrared detector is described herein as an example, any suitable principles and advantages disclosed herein can be implemented in any suitable devices, such as a thermal infrared detector, a terahertz detector, a biomedical imaging system, a pyroelectric imaging array, or an infrared spectrometer.

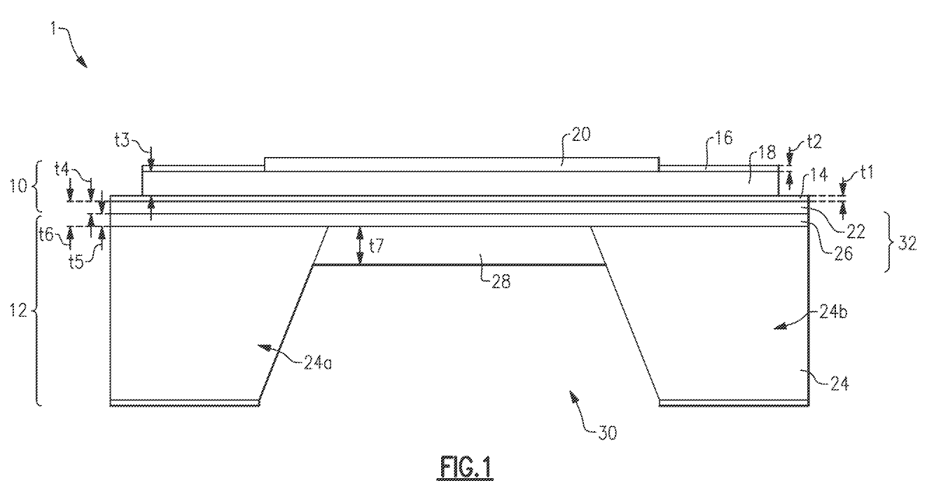

FIG. 1 is a schematic cross-sectional side view of a pyroelectric infrared detector 1 according to an embodiment. The pyroelectric infrared detector 1 can be an example of an uncooled pyroelectric infrared detector. The pyroelectric infrared detector 1 can include a pyroelectric element 10 and a support structure 12 bonded (e.g., covalently bonded) to the pyroelectric element 10.

The pyroelectric element 10 can include a first electrode 14, a second electrode 16, a pyroelectric layer 18 between the first electrode 14 and the second electrode 16, an absorber 20, and a first bonding layer 22 on a surface of the first electrode 14.

The support structure 12 can include a substrate 24, a second bonding layer 26, and a membrane 28. The substrate 24 can have a first portion 24a, a second portion 24b, and a cavity 30 laterally between the first portion 24a and the second portion 24b. The second bonding layer 26 is bonded to the first bonding layer 22. The first bonding layer 22 and the second bonding layer 26 can together define a bonding interface layer 32.

The first electrode 14 and the second electrode 16 can include any suitable material(s). In some embodiments, the first electrode 14 and/or the second electrode 16 can include gold (Au), platinum (Pt), aluminum (Al), indium tin oxide (ITO), or combinations such as chrome/gold (Cr/Au) or titanium/gold (Ti/Au). The first electrode 14 and the second electrode 16 can detect infrared by collecting surface charges generated by the pyroelectric effect in the pyroelectric layer 18 when it experiences temperature changes due to absorbed infrared radiation. These charges create a potential difference between the first electrode 14 and the second electrode 16, which is converted into an electrical signal for further processing.

The pyroelectric layer 18 can include any suitable pyroelectric material(s). In some embodiments, the pyroelectric layer 18 can include a piezoelectric material or a ferroelectric material, such as lithium tantalate (LiTaO₃), lithium niobate (LiNbO₃), barium titanate (BaTiO₃), or lead zirconate titanate (PZT). The pyroelectric layer 18 can include other suitable materials such as polyvinylidene fluoride (PVDF), triglycine sulfate (TGS), or other synthetic or naturally occurring pyroelectric crystals. In some embodiments, an edge of the pyroelectric layer 18 can be offset from an edge of the substrate 24, and a width of the pyroelectric layer 18 can be less than a width of the substrate 24.

The absorber 20 can include any suitable material(s) for absorbing radiation (e.g., infrared radiation). In some embodiments, the absorber 20 can include superlattice materials such as InAs, InSb, InSbAs, or InGaAs, or bulk semiconductors and semiconductor alloys customized for infrared absorption. The absorber 20 can absorb infrared by converting incident infrared radiation into heat, which is then transmitted to the pyroelectric layer. This process can be enhanced by tailoring the energy bandgap, absorption strength, and strain balance of the absorber material. Additionally, the absorber 20 may be configured with chirped superlattice structures to create graded energy bandgaps, unipolar barriers for hole or electron blocking, and multilayer designs for specific infrared wavelength sensitivity. In some embodiments, the second electrode 16 can be positioned between the absorber 20 and the pyroelectric layer 18.

The first bonding layer 22 and the second bonding layer 26 can include any suitable material(s) that enables direct bonding, such as covalent bonding. In some embodiments, the first bonding layer 22 and the second bonding layer 26 can be an oxide layer. For example, the first bonding layer 22 and the second bonding layer 26 can include silicon dioxide. In some other embodiments, the first bonding layer 22 and the second bonding layer 26 can include materials such as silicon nitride (Si₃N₄), amorphous silicon (a-Si), organic bonding materials like benzocyclobutene (BCB), plasma-enhanced silicon dioxide, or spin-on glass (SOG) formulations. There can be a bonding interface in the bonding interface layer 32 between the first bonding layer 22 and the second bonding layer 26. Because the first bonding layer 22 and the second bonding layer 26 are directly bonded without an intervening adhesive, a thickness of the bonding interface layer 32 can be the total thickness of the first bonding layer 22 and the second bonding layer 26.

The substrate 24 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The substrate 24 can have a relatively high thermal conductivity. For example, a thermal conductivity of the substrate 24 can be higher than a thermal conductivity of the pyroelectric layer 18.

The membrane 28 can be positioned between the cavity 30 and the pyroelectric element 10. In some embodiments, the membrane 28 can be in contact with the second bonding layer 26. The membrane 28 can include any suitable material(s). In some embodiments, the membrane can include materials with low thermal conductivity, low thermal mass, and high mechanical stability to minimize heat loss and enhance sensitivity. For example, the membrane can include silicon nitride (SiN), silicon dioxide (SiO₂), or combinations thereof, as they can provide thermal isolation and mechanical support for the pyroelectric element 10.

The first electrode 14 has a thickness t1; the second electrode 16 has a thickness t2; the pyroelectric layer 18 has a thickness t3; the first bonding layer 22 has a thickness t4, the second bonding layer 26 has a thickness t5, the bonding interface layer 32 has a thickness t6, and the membrane 28 has a thickness t7. In some embodiments, the thickness t1 of the first electrode 14 can be in a range between 1 nanometer and 100 nanometers, 10 nanometers and 100 nanometers, 25 nanometers and 100 nanometers, 10 nanometers and 75 nanometers, or 10 nanometers and 50 nanometers. In some embodiments, the thickness t2 of the second electrode 16 can be in a range between 1 nanometer and 100 nanometers, 10 nanometers and 100 nanometers, 25 nanometers and 100 nanometers, 10 nanometers and 75 nanometers, or 10 nanometers and 50 nanometers. In some embodiments, the thickness t3 of the pyroelectric layer 18 can be in a range between 0.5 micrometers and 7 micrometers, 1 micrometer and 7 micrometers, or 1 micrometer and 5 micrometers. In some embodiments, the thickness t4 of the first bonding layer 22 can be in a range between 0.1 micrometers and 1 micrometer, 0.3 micrometers and 1 micrometer, or 0.3 micrometers and 0.7 micrometers. The thickness t4 of the first bonding layer 22 can be less than 0.5 micrometers. In some embodiments, the thickness t5 of the second bonding layer 26 can be in a range between 0.1 micrometers and 1 micrometer, 0.3 micrometers and 1 micrometer, or 0.3 micrometers and 0.7 micrometers. The thickness t5 of the second bonding layer 26 can be less than 0.5 micrometers. In some embodiments, the thickness t6 of the bonding interface layer 32 can be in a range between 0.2 micrometers and 2 micrometers, 0.6 micrometers and 2 micrometers, 0.6 micrometers and 1.4 micrometers, or 0.8 micrometers and 1.2 micrometers. The thickness t6 of the bonding interface layer 32 can be less than 1 micrometer. In some embodiments, the thickness t7 of the membrane 28 can be in a range between 15 micrometers and 35 micrometers, 15 micrometers and 30 micrometers, or 20 micrometers and 30 micrometers.

The pyroelectric infrared detector 1 can be manufactured in any suitable manner. An example method of forming the pyroelectric infrared detector 1 will be described below.

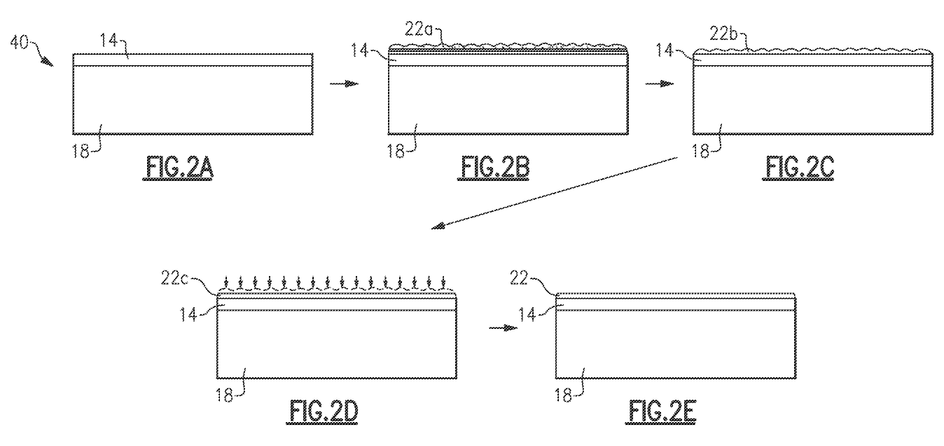

FIG. 2A is a schematic cross-sectional side view of a pyroelectric structure 40. The pyroelectric structure 40 can include a pyroelectric layer 18 and a first electrode 14. The first electrode 14 can be formed on a surface of the pyroelectric layer 18. The pyroelectric layer 18 in the pyroelectric structure 40 can have a thickness that is greater than the thickness t3 of the pyroelectric layer 18 in the final product (e.g., in the pyroelectric element 10).

FIG. 2B is a schematic cross-sectional side view of the pyroelectric structure 40 with a bonding layer 22a. In some embodiments, the bonding layer 22a can be an oxide layer. The bonding layer 22a can be provided by way of, for example, deposition. FIG. 2C is a schematic cross-sectional side view of the pyroelectric structure 40 with a bonding layer 22b after densifying the bonding layer 22a. For example, the bonding layer 22a can be annealed at a temperature in a range between 220° C and 280° C for a duration in a range between 2 hours and 4 hours to form the densified bonding layer 22b. In some embodiments, the bonding layer 22a can be annealed at a temperature below 250° C.

FIG. 2D is a schematic cross-sectional side view of the pyroelectric structure 40 with a bonding layer 22c during a polishing process. FIG. 2E is a schematic cross-sectional side view of the pyroelectric structure 40 with a first bonding layer 22 after the polishing process. The bonding layer 22b can be polished by way of, for example, chemical mechanical polishing. The polishing process can partially remove a portion of the bonding layer 22b. The polishing process can be part of a surface preparation process for preparing the surface of the first bonding layer 22 for bonding.

The second bonding layer 26 of the support structure 12 can be formed in a similar manner as described with respect to the first bonding layer 22 in FIGS. 2B-2E. For example, the second bonding layer 26 can be provided by depositing a bonding layer, densifying the bonding layer, and polishing the bonding layer.

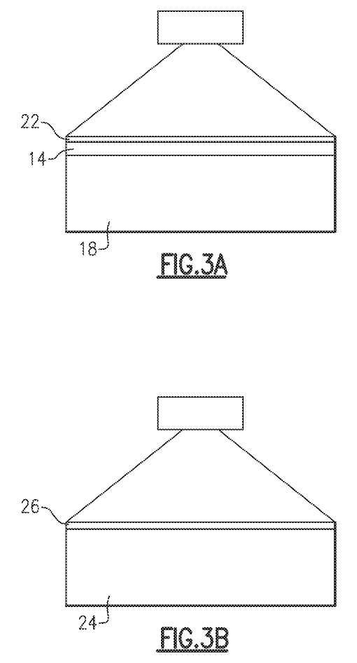

In some embodiments, the first bonding layer 22 and/or the second bonding layer 26 can be surface-treated. FIG. 3A is a schematic cross-sectional side view of the pyroelectric structure 40 with the first bonding layer 22 in a surface treatment process. FIG. 3B is a schematic cross-sectional side view of the substrate 24 with the second bonding layer 26 in a surface treatment process. The surface-treatment processes can be part of a surface preparation process for preparing the surfaces of the first and second bonding layers 22, 26 for bonding. The surface treatment process of treating the first bonding layer 22 and/or the second bonding layer 26 can include plasma activation and/or ultraviolet irradiation.

Plasma treatment can include a surface activation process that enhances bond strength and quality by increasing the reactivity and cleanliness of the surfaces. The process can include exposing the surfaces of the first and second bonding layers 22, 26 to a plasma, generated using gases, such as, for example, oxygen, argon, or a mixture such as O₂/N₂. The plasma can be created by ionizing the gas using high-frequency RF or microwave fields, producing reactive species like ions, radicals, and electrons. These reactive species interact with the first and second bonding layers 22, 26, breaking chemical bonds and introducing reactive groups, such as hydroxyl (–OH) groups, which increase surface hydrophilicity and energy. The activated surfaces of the first and second bonding layers 22, 26 can be brought into contact in a clean environment, where initial bonding occurs through Van der Waals and hydrogen bonds. To further strengthen the bond, an optional annealing step at 200–400° C promotes condensation reactions that form covalent bonds and release water as a byproduct.

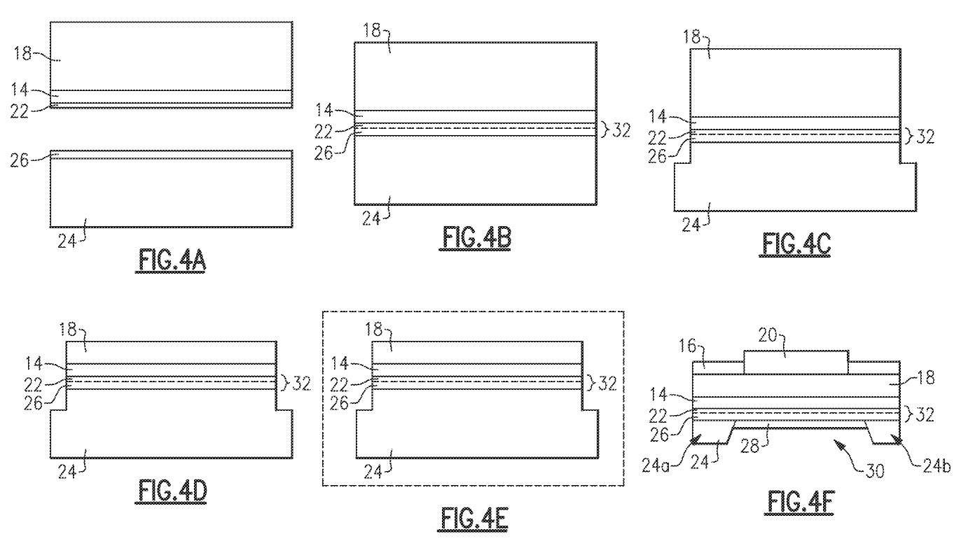

FIG. 4A is a schematic cross-sectional side view of the pyroelectric structure 40 with the first bonding layer 22 and the substrate 24 with the second bonding layer 26 prior to bonding. FIG. 4B is a schematic cross-sectional side view of the pyroelectric structure 40 with the first bonding layer 22 and the substrate 24 with the second bonding layer 26 after bonding. The first bonding layer 22 and the second bonding layer 26 can be bonded to form a bonding interface layer 32. In some embodiments, mechanical pressure can be applied to bond the first bonding layer 22 and the second bonding layer 26. In some embodiments, the first bonding layer 22 and the second bonding layer 26 can be bonded at room temperature by way of, for example, room-temperature fusion bonding. For example, the first bonding layer 22 and the second bonding layer 26 can be covalently bonded. In the bonding interface layer 32, there may be a bonding interface indicative of two separate layers (the first bonding layer 22 and the second bonding layer 26) bonded together.

FIG. 4C is a schematic cross-sectional side view of the pyroelectric structure 40 with the first bonding layer 22 and the substrate 24 with the second bonding layer 26 after edge trimming. The structure shown in FIG. 4C may be a portion of the structure shown in FIG. 4B, and a plurality of the structures of FIG. 4C may be formed from the structure shown in FIG. 4B in some applications.

FIG. 4D is a schematic cross-sectional side view of the pyroelectric structure 40 with the first bonding layer 22 and the substrate 24 with the second bonding layer 26 after a thinning process. A portion of the pyroelectric layer 18 can be removed to adjust the thickness of the pyroelectric layer 18. The thinning process can include grinding. In some embodiments, a thinned surface of the pyroelectric layer 18 can be smoothed by way of, for example, chemical-mechanical polishing.

FIG. 4E is a schematic cross-sectional side view of the pyroelectric structure 40 with the first bonding layer 22 and the substrate 24 with the second bonding layer 26 during an annealing process. For example, the bonding interface layer 32 can be annealed at a temperature in a range between 220° C and 280° C for a duration in a range between 2 hours and 4 hours. In some embodiments, the bonding interface layer 32 can be annealed at a temperature below 250° C.

FIG. 4F is a schematic cross-sectional side view of the pyroelectric infrared detector 1. The pyroelectric infrared detector 1 includes a second electrode 16, an absorber 20, a membrane 28, and a cavity 30. In some embodiments, the second electrode 16 can be patterned on the pyroelectric layer 18. The absorber 20 can be provided over the pyroelectric layer 18. In some embodiments, the absorber 20 can be positioned laterally between portions of the second electrode 16. In some other embodiments, a portion of the second electrode 16 can be positioned between the pyroelectric layer 18 and the absorber 20.

The cavity 30 can be formed by removing (e.g., etching) at least a portion of the substrate 24. In some embodiments, the cavity 30 can be formed by etching completely through a thickness of the substrate 24 and exposing the second bonding layer 26. In some other embodiments, the etching process may etch partially through the thickness of the substrate 24 and leave a portion of the substrate 24 between the second bonding layer 26 and the cavity 30. In some other embodiments, the etching process may remove at least a portion of the bonding interface layer 32. In such embodiments, the thickness t6 of the bonding interface layer 32 can have a thick region and a thin region. In some embodiments, a sidewall of the cavity can be tapered or angled as a result of the etching process.

The membrane 28 can be formed by, for example, partially filling the cavity with a membrane material (e.g., SiO₂ or Si₃N₄). For example, the membrane material can be deposited. The membrane 28 can be in contact with the sidewall of the cavity 30 formed in the substrate 24 and be positioned between a first portion 24a and a second portion 24b of the substrate 24. The membrane 28 can be in contact with a portion of the bonding interface layer 32 or the first electrode 14. After the pyroelectric infrared detector 1 is formed, the pyroelectric infrared detector 1 can be packaged and/or integrated in a larger system or substrate.

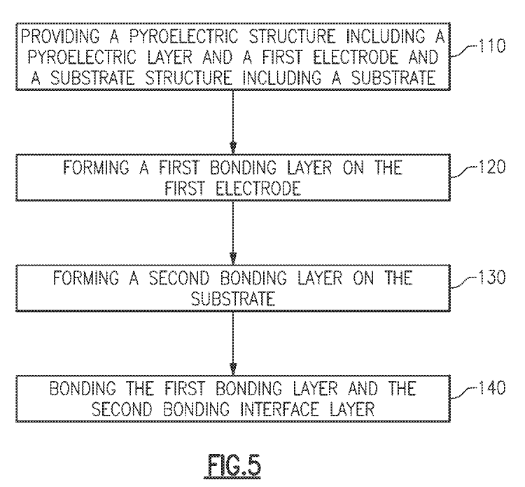

FIG. 5 is a flowchart of a method of forming a pyroelectric detector according to an embodiment. At block 110, a pyroelectric structure including a pyroelectric layer and a first electrode and a substrate structure including a substrate can be provided. At block 120, a first bonding layer on the first electrode can be formed. At block 130, a second bonding layer on the substrate can be formed. At block 140, the first bonding layer and the second bonding layer can be bonded to form a bonding interface layer.

Aspects of this disclosure can be implemented in various electronic devices. Examples of the electronic devices can include, but are not limited to, consumer electronic products and parts of consumer electronic products, such as motion sensors, gas analyzers, and temperature monitoring components. Additional examples of electronic devices can include, but are not limited to, home automation devices (e.g., smart thermostats, automated lighting systems), security systems (e.g., intrusion detectors, surveillance cameras), thermal imaging systems, medical devices (e.g., thermometers, diagnostic imaging tools), industrial equipment (e.g., process monitors, flame detectors), and environmental monitoring systems. Other examples of electronic devices can include portable or wearable devices such as smart watches, fitness trackers, and smartphones equipped with IR sensing capabilities. Pyroelectric detectors can also be integrated into vehicular systems for driver monitoring, automated climate control, or night vision applications. Further, these devices can be used in laboratory instrumentation, spectrometry equipment, or other advanced sensing systems. The electronic devices can include both finished products and unfinished products intended for assembly or integration into larger systems.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A pyroelectric detector comprising:
a pyroelectric element including a first electrode, a second electrode, a pyroelectric layer between the first electrode and the second electrode, an absorber, and a first bonding layer; and
a support structure including a substrate having a cavity, a membrane, and a second bonding layer bonded to the first bonding layer to define a bonding interface layer, the cavity and the membrane being positioned laterally between portions of the substrate.

2. The pyroelectric detector of claim 1 wherein the first bonding layer and the second bonding layer are oxide layers.

3. The pyroelectric detector of claim 1 wherein the membrane includes silicon nitride.

4. The pyroelectric detector of claim 1 wherein the first bonding layer has a thickness in a range between 0.3 micrometers and 0.7 micrometers.

5. The pyroelectric detector of claim 1 wherein the second bonding layer has a thickness in a range between 0.3 micrometers and 0.7 micrometers.

6. The pyroelectric detector of claim 1 wherein the membrane has a thickness in a range between 20 micrometers and 30 micrometers.

7. The pyroelectric detector of claim 1 wherein the membrane is in contact with the bonding interface layer.

8. The pyroelectric detector of claim 1 wherein the membrane is in contact with the first electrode.

9. The pyroelectric detector of claim 1 wherein the substrate includes silicon or sapphire.

10. The pyroelectric detector of claim 1 wherein the cavity has a tapered sidewall.

11. The pyroelectric detector of claim 1 wherein the pyroelectric layer includes lithium tantalate or lithium niobate.

12. The pyroelectric detector of claim 1 wherein the absorber is an infrared absorber.

13. A pyroelectric detector comprising:
a substrate having a first portion, a second portion, and a cavity laterally between the first portion and the second portion;
a pyroelectric layer between a first electrode and a second electrode, the pyroelectric layer coupled to the substrate; and
a membrane positioned laterally between the first portion and the second portion of the substrate, a thickness of the membrane being in a range between 20 micrometers and 30 micrometers.

14. The pyroelectric detector of claim 13 wherein the membrane includes silicon nitride.

15. The pyroelectric detector of claim 13 wherein the membrane has a thickness in a range between 15 micrometers and 30 micrometers.

16. The pyroelectric detector of claim 13 further comprising a bonding interface layer between the substrate and the first electrode, wherein the membrane is in contact with the bonding interface layer.

17. The pyroelectric detector of claim 13 wherein the membrane is in contact with the first electrode.

18. The pyroelectric detector of claim 13 wherein the substrate includes silicon or sapphire.

19. The pyroelectric detector of claim 13 wherein the cavity has a tapered sidewall.

20. The pyroelectric detector of claim 13 wherein the pyroelectric layer includes lithium tantalate or lithium niobate.
